(19) United States
(12) Patent Application Publication
(10) Pub. No.: US 2026/0023327 A1
(43) Pub. Date: Jan. 22, 2026

(54) SQUARE PIXEL PATTERNS FOR HIGH RESOLUTION DIGITAL LITHOGRAPHY

(71) Applicant: Applied Materials, Inc., Santa Clara, CA (US)

(72) Inventors: Jong Yun Kim, Hwaseong-si (KR); Glen T. Mori, Gilroy, CA (US); Ya Ti Hsiao, Taichung City (TW); Young Ho Kim, Seongnam-si (KR)

(21) Appl. No.: 19/260,958

(22) Filed: Jul. 7, 2025

Related U.S. Application Data
(60) Provisional application No. 63/672,782, filed on Jul. 18, 2024.

(51) Int. Cl. G03F 7/00

(52) U.S. Cl. CPC G03F 7/704; G03F 7/70116

(57) ABSTRACT

A system includes a memory and at least one processing device, operatively coupled to the memory, to generate a square pixel pattern for rasterizing an image, rasterize the image using the square pixel pattern to generate a raster image, wherein the raster image is stored in a file usable by a digital lithography system, and cause the digital lithography system to pattern a substrate based on the raster image having the square pixel pattern.

### CROSS-REFERENCE TO RELATED APPLICATION(S)

The present application claims the benefit of U.S. Provisional Patent Application No. 63/672,782, filed on Jul. 18, 2024, the entire contents of which are hereby incorporated by reference herein.

### TECHNICAL FIELD

The instant specification generally relates to electronic device fabrication. More specifically, the instant specification relates to square pixel patterns for high resolution digital lithography.

### BACKGROUND

Photolithography is a process used in the manufacturing of electronic devices (e.g., integrated circuits (ICs) that involves using light, such as laser light, ultraviolet light (UV), near-UV, etc., to transfer a pattern onto a substrate (e.g., a wafer). Digital lithography generally refers to processes that use a virtual mask file to cause light to expose a photoresist to create patterns on a substrate without the use of a physical mask. More particularly, digital lithography technology can be used to directly expose patterns onto photoresist films without the use of masks. Examples of digital lithography include maskless lithography, direct-write lithography, etc. For example, digital lithography technology can provide high speed and high-resolution maskless lithography solutions to for printed circuit board (PCB) patterning, solder masks, flat panel displays, laser marking, and other digital exposure systems that benefit from high speed and precision. Direct exposure increases productivity compared to narrow laser beam or masked systems. An advantage of digital lithography is the ability to change lithography patterns from one run to the next, without incurring the cost of generating a new photomask. Illustratively, digital lithography can be used to perform large-area patterning during electronic device fabrication. Accordingly, digital lithography technology can reduce material cost, improve production rates, and allow for rapid changes of patterns as compared to other lithography technologies (e.g., masked-based lithography technologies).

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In accordance with an embodiment, a system is provided. The system includes a memory and at least one processing device, operatively coupled to the memory, to generate a square pixel pattern for rasterizing an image, rasterize the image using the square pixel pattern to generate a raster image, wherein the raster image is stored in a file usable by a digital lithography system, and cause the digital lithography system to pattern a substrate based on the raster image having the square pixel pattern.

In accordance with another embodiment, a method is provided. The method includes generating, by at least one processing device, a square pixel pattern for rasterizing an image, rasterizing, by the at least one processing device, the image using the square pixel pattern to generate a raster image, wherein the raster image is stored in a file usable by a digital lithography system, and causing, by the at least one processing device, the digital lithography system to pattern a substrate based on the raster image having the square pixel pattern.

In accordance with yet another embodiment, a non-transitory computer-readable storage medium is provided. The non-transitory computer-readable storage medium includes instructions that, when executed by at least one processing device, cause the at least one processing device to perform operations including generating a square pixel pattern for rasterizing an image, rasterizing the image using the square pixel pattern to generate a raster image, wherein the raster image is stored in a file usable by a digital lithography system, and causing the digital lithography system to pattern a substrate based on the raster image having the square pixel pattern.

### BRIEF DESCRIPTION OF THE DRAWINGS

Aspects and implementations of the present disclosure will be understood more fully from the detailed description given below and from the accompanying drawings, which are intended to illustrate aspects and implementations by way of example and not limitation.

FIG. 1 is a schematic partial perspective view of a digital lithography system, in accordance with some embodiments.

FIG. 2 is a block diagram of a digital lithography system, in accordance with some embodiments.

FIG. 3 is a diagram of a digital lithography system, in accordance with some embodiments.

FIGS. 4A-4B are diagrams illustrating example rasterizations of images, in accordance with some embodiments.

FIGS. 5A-5D are diagrams illustrating an example operation of a digital lithography system, in accordance with some embodiments.

FIG. 6 are diagrams illustrating example steps of implementing square pixel patterns for high resolution digital lithography, in accordance with some embodiments.

FIG. 7 is a diagram illustrating an example of applying periodicity conditions used to implement square pixel patterns for high resolution digital lithography, in accordance with some embodiments.

FIG. 8 are diagrams illustrating an example of confining values of a first axis to number of lines perpendicular to the first axis used to implement square pixel patterns for high resolution digital lithography, in accordance with some embodiments.

FIG. 9 are diagrams illustrating an example of confining values of a second axis to number of lines perpendicular to the second axis used to implement square pixel patterns for high resolution digital lithography, in accordance with some embodiments.

FIGS. 10A-10C are diagrams illustrating example implementations of square pixel patterns for high resolution digital lithography, in accordance with some embodiments.

FIG. 11 is a flow chart of an example method for implementing square pixel patterns for high resolution digital lithography, in accordance with some embodiments.

FIG. 12 is a block diagram illustrating a computer system, according to certain embodiments.

### DETAILED DESCRIPTION

Some digital lithography systems are implemented using digital micromirror devices (DMDs). A DMD is an electrical input, optical output micro-electrical-mechanical system (MEMS) that can perform spatial light modulation. More specifically, a DMD can include an array of micromirrors (“mirrors”) that can be individually tilted to reflect light in different directions. Each mirror can be tilted into two positions: ON (reflecting light) or OFF (deflecting light). Each mirror acts as a pixel, and by rapidly switching mirrors between on and off positions, the DMD can modulate light to create images or patterns. When used with coherent light sources like lasers, a DMD can produce diffraction patterns due to their structure. The arrangement of the mirrors of a DMD can create a grating effect that causes incident light to be diffracted into multiple orders. For a coherent light source, the diffraction pattern produced by the DMD can be distributed in a dotted pattern that results from the interference between light reflected from different micromirrors. The color of the dot pattern can depend on the wavelength of the light source used.

To perform digital lithography with a DMD, the DMD can project an image (e.g., shape) onto a photoresist on the substrate by controlling a position of each of the mirrors. More specifically, the mirrors in the ON position can reflect the light onto the photoresist, exposing the light to the image at a particular location (“a dose”). The mirrors in the OFF position deflect the light away from the photoresist. The exposed photoresist can be developed to remove either the exposed or unexposed areas, depending on the type of photoresist. The development of the exposed photoresist leaves behind the image on the substrate. Accordingly, by using a combination of mirrors in an ON position and an OFF position, the photoresist can be selectively exposed to light that, when developed, create the image on the substrate.

To perform digital lithography, a digital image having a vector graphics format can first be converted into a format compatible with the digital lithography system (e.g., DMD-compatible format), also referred to as an exposure pattern. Converting the digital image into the exposure pattern can include rasterizing the image to generate a raster image having a bitmap format. A bitmap refers to a matrix pattern of pixels (or dots) that represent the original image. For example, the image can be defined by a virtual mask file, such as a GDSII stream format (“GDS”) file, where GDS stands for Graphic Design System. GDS is a binary database file format that can represent planar geometric shapes, text labels, and other information about the layout in hierarchical form. Vector format images are typically rasterized into raster images using hexagon shaped pixel patterns. However, images that are frequently used by digital lithography systems for projection onto substrates include straight lines, such as horizontal lines, vertical lines and 45 degree (e.g., oblique) lines. To that end, hexagon shaped pixel patterns may not be optimal to use to generate raster images for digital lithography, as they may contribute to line edge roughness (LER) and/or line width roughness (LWR). The LER and/or LWR that can result from using non-symmetrical and/or non-orthogonal pixel pattern shapes, such as hexagon pixel patterns, is one factor that can impede higher resolution digital lithography (e.g., sub-micron digital lithography).

Aspects and implementations of the present disclosure address these and other shortcomings of existing technologies by implementing square pixel patterns for high resolution digital lithography. A square pixel pattern is a pixel pattern having a (non-rotated) square shape. Square pixel patterns described herein can be used to generate raster images in a manner that can improve resolution with reduced LER and LWR. Additionally, square pixel patterns described herein can rasterize diagonal lines better than other shaped patterns (e.g., hexagon pixel patterns). Further details regarding square pixel patterns and using square pixel patterns to generate raster images will be described in further detail below.

Embodiments described herein can be used to improve the manufacture of various electronic devices. For example, embodiments described herein can be used to improve advanced packaging techniques. Advanced packaging, in the context of electronic devices (e.g., semiconductor devices), refers to a collection of techniques used to combine multiple components (e.g., chips) into a single package. That is, advanced packaging refers to the aggregation and interconnection of components before traditional integrated circuit packaging where a single die is packaged. Advanced packaging can be used to fabricate smaller, more powerful, and more efficient electronic devices. For example, advanced packaging can enable the formation of shorter interconnects between components, which can reduce signal delay, improve performance, and reduce power consumption. As another example, advanced packaging can integrate different types of components (e.g., processors, memory, sensors) into a single package. Examples of advanced packaging techniques include 2.5D packaging, 3D packaging, fan-out wafer-level packaging (FOWLP), system-in-package, quilt packaging, etc.

Aspects and implementations of the present disclosure result in technological advantages over other approaches. For example, using square pixel patterns described herein can reduce LER and LWR resulting from digital lithography utilizing DMDs, which can achieve improved substrate patterning results as compared to other pixel patterns such as hexagon pixel patterns.

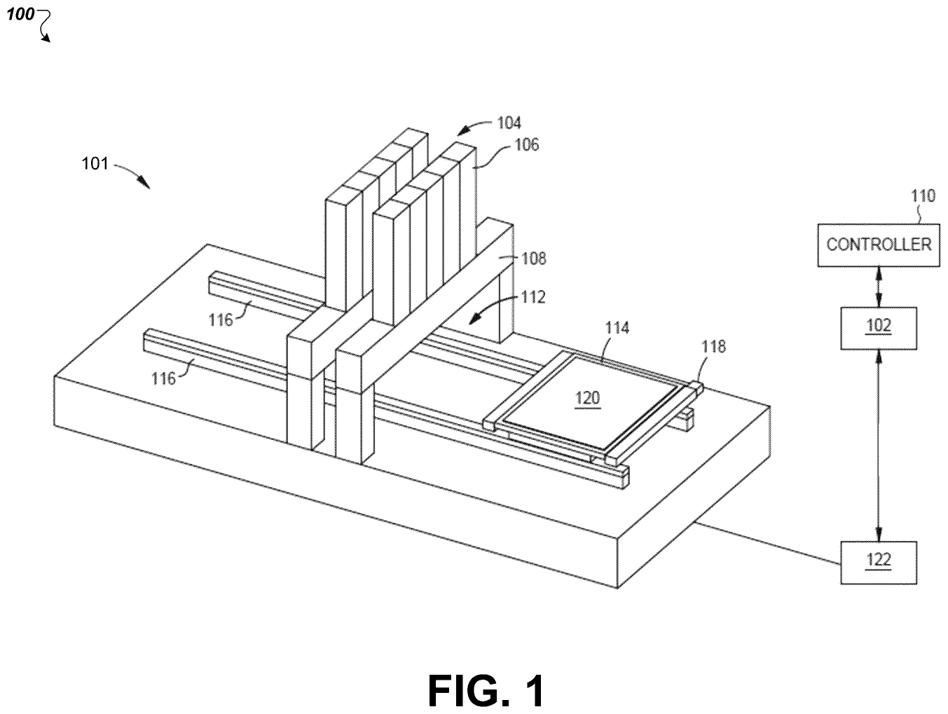

FIG. 1 is a schematic partial perspective view of a digital lithography system (“system”) 100, in accordance with some embodiments. For example, the system 100 can implement a DMD. The system 100 can include a digital lithography subsystem (“subsystem”) 101. The subsystem 101 can include a stage 114 and a processing unit 104. The stage 114 is supported by a pair of tracks 116. A substrate 120 is supported by the stage 114. The stage 114 is operable to move along the pair of tracks 116. The stage 114 can move on the tracks 116 in the x-direction and the y-direction as defined in FIG. 1. The processing unit 104 is configured to expose the photoresist in the digital lithography process using one or more image projection systems (IPS) 106. The IPS 106 are supported by supports 108 that are adjacent to (e.g., straddle) the pair of tracks 116. The supports 108 provide an opening 112 for the pair of tracks 116 and the stage 114 to pass under the processing unit 104. The subsystem 101 can further include an encoder coupled to a stage.

The substrate 120 can be formed from any suitable material or combinations of materials, for example, glass, which is used as part of a flat panel display. In other embodiments, which can be combined with other embodiments described herein, the substrate 120 is made of other materials capable of being used as a part of the flat panel display. The substrate 120 has a film layer to be patterned formed thereon, such as by pattern etching thereof, and a photoresist layer formed on the film layer to be patterned, which is sensitive to electromagnetic radiation (e.g., UV). A positive photoresist includes portions of the photoresist, when exposed to radiation, are respectively soluble to a photoresist developer applied to the photoresist after the pattern is written into the photoresist using the electromagnetic radiation. A negative photoresist includes portions of the photoresist, when exposed to radiation, will be respectively insoluble to photoresist developer applied to the photoresist after the pattern is written into the photoresist using the electromagnetic radiation. The chemical composition of the photoresist determines whether the photoresist is a positive photoresist or negative photoresist. Examples of photoresists include, but are not limited to, at least one of diazonaphthoquinone, a phenol formaldehyde resin, poly(methyl methacrylate), poly(methyl glutarimide), and SU-8. After exposure of the photoresist to the electromagnetic radiation, the resist is developed to leave an exposure underlying film layer. Then, using the patterned photoresist, the underlying thin film is pattern etched through the openings in the photoresist to form a portion of the electronic circuitry of the display panel.

The system 100 can further include a lithography controller 122 and a controller 110 communicably coupled to the subsystem 101. For example, the encoder 118 can provide information regarding the location of the stage 114 to the lithography controller 122. The lithography controller 122 is generally designed to facilitate the control and automation of the processing techniques described herein. The lithography controller 122 may be coupled to or in communication with the processing unit 104, the stage 114, and the encoder 118. The processing unit 104 and the encoder 118 may provide information to the lithography controller 122 regarding the substrate processing and the substrate aligning. For example, the processing unit 104 may provide information to the lithography controller 122 to alert the lithography controller 122 that substrate processing has been completed. The controller 110 is operable to deliver one or more virtual mask files corresponding to exposure patterns or the controller 110 is otherwise configured to perform processes described herein. The lithography controller 122 can facilitate the control and automation of a digital lithography process based on a virtual mask file provided by a virtual mask software application 102. The virtual mask file, readable by the lithography controller 122, determines which tasks are to be performed on a substrate. The virtual mask file corresponds to an exposure pattern to be written into the photoresist using the electromagnetic radiation.

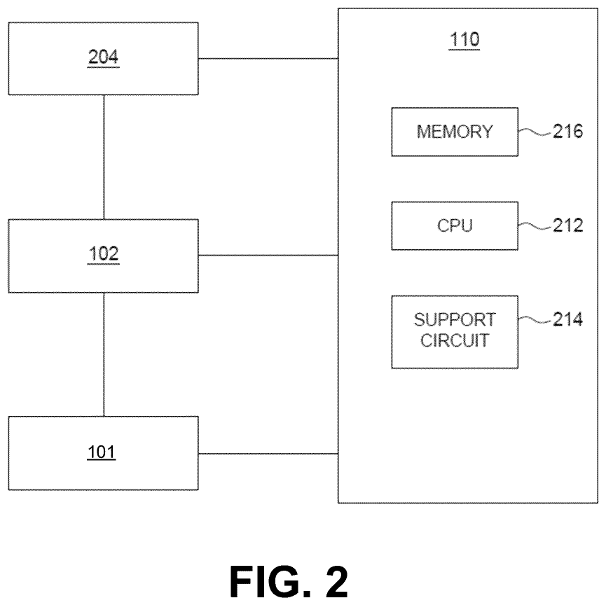

The processing unit 104 can include a pattern generator configured to receive a virtual mask file from the virtual mask software application 102. The virtual mask file can be provided to the processing unit 104 via the lithography controller 122. The processing unit 104 is configured to expose the photoresist in the digital lithography process using the IPS 106. The IPS 106 are operable to project write beams of electromagnetic radiation to the substrate 120. The exposure pattern generated by the processing unit 104 is projected by the IPS 106 to expose the photoresist of the substrate 120 to the exposure pattern. The exposure of the photoresist forms one or more different features in the photoresist. In one embodiment, which can be combined with other embodiments described herein, each of the IPS 106 includes a spatial light modulator to modulate the incoming light to create the desired image. Each spatial light modulator includes electrically addressable elements that may be controlled individually. Each electrically addressable element may be in an “ON” position or an “OFF” position based on the digital pattern file 204 (shown in FIG. 2). When the light reaches the spatial light modulator, the electrically addressable elements that are in the “ON” position project write beams to a projection lens (not shown). The projection lens then projects the write beams to the substrate 120. The electrically addressable elements include, but are not limited to, digital micromirrors, liquid crystal displays (LCDs), liquid crystal over silicon (LCoS) devices, ferroelectric liquid crystal on silicon (FLCoS) devices, microshutters, microLEDs, VCSELs, liquid crystal displays (LCDs), or any solid state emitter of electromagnetic radiation.

FIG. 2 is a block diagram of a digital lithography system (“system”) 200, in accordance with some embodiments. As shown, the system 200 can include the subsystem 101, the virtual mask software application 102 and the controller 110 described above with reference to FIG. 1. The controller 110 is operable to facilitate the transfer of a digital pattern file 204 (e.g., data) provided to the controller 110. The controller 110 is operable to execute a virtual mask software application 102 to convert the digital pattern file 204 into a virtual mask file (not shown) having an exposure pattern readable by the processing unit 104. Each of the lithography environment devices is operable to be connected to each other via the subsystem 101. Each of the lithography environment devices is operable to be connected to the controller 110 by the subsystem 101. The system 200 can be located in the same area or production facility, or the each of the lithography environment devices can be located in different areas.

The controller 110 includes a central processing unit (CPU) 212, support circuits 214 and a memory 216. The CPU 212 can be one of any form of computer processor that can be used in an industrial setting for controlling the lithography environment devices. The memory 216 is coupled to the CPU 212. The memory 216 can be one or more of readily available memory, such as random access memory (RAM), read only memory (ROM), floppy disk, hard disk, or any other form of digital storage, local or remote. The support circuits 214 are coupled to the CPU 212 for supporting the processor. For example, the support circuits 214 can include cache, power supplies, clock circuits, input/output circuitry, subsystems, and the like. The CPU 212 can be coupled to input/output (I/O) devices found in the support circuits 214 and the memory 216. The controller 110 is operable to facilitate and transfer the digital pattern file 204 to the system 100 via the subsystem 101. The digital pattern file 204 is operable to be provided to the virtual mask software application 102 or the system 100 via the controller 110.

The memory 216 can include one or more software applications, such as the virtual mask software application 102. The CPU 212 can be a hardware unit or combination of hardware units capable of executing software applications and processing data. In some configurations, the CPU 212 includes a digital signal processor (DSP), an application-specific integrated circuit (ASIC), and/or a combination of such units. The CPU 212 is configured to execute the one or more software applications, such as the virtual mask software application 102 and process the stored media data, which can be each included within the memory 216. The controller 110 controls the transfer of data and files to and from the various lithography environment devices.

The controller 110 is operable to receive exposure patterns of the virtual mask file and transfer the exposure patterns to the system 100 via the subsystem 101. The virtual mask file (or computer instructions), which may be referred to as an imaging design file, readable by the controller 110, determines which tasks are performable on a substrate. While the virtual mask software application 102 is illustrated as separate from the controller 110 (e.g., in the cloud), it is contemplated that the virtual mask software application 102 may be stored locally (e.g., in memory 216).

The virtual mask file corresponds to a pattern to be written into the photoresist using electromagnetic radiation output by the system 100. In one embodiment, which can be combined with other embodiments described herein, the pattern may be formed with one or more patterning devices. For example, the one or more patterning devices are configured to perform ion-beam etching, reactive ion etching, electron-beam (e-beam) etching, wet etching, nanoimprint lithography (NIL), and combinations thereof. The virtual mask file may be provided in different formats. For example, the format of the virtual mask file may be one of a GDS format, and an OASIS format, among others. The virtual mask file includes information corresponding to features of exposure patterns to be generated on a substrate (e.g., the substrate 120). The virtual mask file may include areas of interest which correspond to one or more structural elements. The structural elements may be constructed as geometrical shapes (e.g., polygons).

The lithography model can be a physics based model. For example, the lithography model can use either a scalar or vector imaging model. In some embodiments, the lithography model utilizes a matrix defined by optical properties and/or photoresist properties. For example, the matrix can include Transmission Cross Coefficients (TCC). In some embodiments, other numerical simulation techniques such as Resolution Enhancement Technology (RET), Optical Proximity Correction (OPC), and Source Mask Optimization (SMO) may be utilized. However, all such models and modeling techniques, whether now known or later developed, are intended to be within the scope of the present disclosure. The lithography model can be constructed to be defined based on optical properties (e.g., optical properties relating to the system 100) and the photoresist properties (e.g., properties of the photoresist of which the pattern will be printed on such as materials and processing characteristics of the photoresist). The photoresist properties include numerical aperture, exposure, illumination type, size of illumination, and wavelength, and may include other values.

Once the lithography model is constructed, the virtual mask file can be provided as input to the lithography model. The lithography model can then output a prediction of the aerial image and resist profile of the virtual mask file. Through post-processing operations, the ILS and depth of focus of features formed in a photoresist of a substrate based on the virtual mask file may be determined. The lithography model will utilize numerical calculations to predict variables to achieve the maximum ILS and depth of focus (or a maximum ILS and depth of focus within other predefined constraints). The variables include a width and position and a pattern bias value of the exposure patterns. The numerical calculations may be iterative methods, level-set methods, or any other numerical methods operable to solve the lithography model.

The controller 110 provides the digital pattern file 204 to the virtual mask software application 102. The virtual mask software application 102 is operable to receive the digital pattern file 204 via the subsystem 101. The virtual mask software application 102 can be a vMASC software. In one embodiment, which can be combined with other embodiments described herein, the virtual mask software application 102 is a software program stored in the memory 216 of the controller 110. The CPU 212 is configured to execute the software program. In another embodiment, which can be combined with other embodiments described herein, the virtual mask software application 102 may be a remote computer server which includes a controller and a memory (e.g., data store).

The digital pattern file 204 can be converted into one or more virtual mask files by the virtual mask software application 102. For example, a first virtual mask file may correspond to an exposure pattern and a second virtual mask file may correspond to another exposure pattern. The virtual mask file is a digital representation of the design to be printed by the system 100. The virtual mask file is provided to the system 100 via the subsystem 101. The virtual mask file is stored in the system 100.

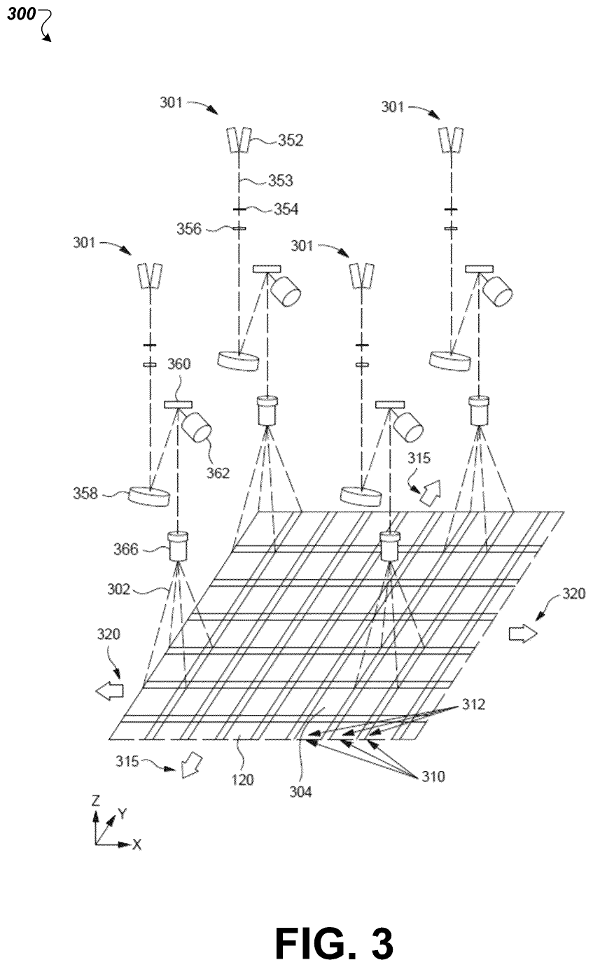

FIG. 3 is a diagram of a system 300 including multiple IPS 301, in accordance with some embodiments. As shown in FIG. 3, each of the IPS 301 can generate write beams 302 onto a surface 304 of the substrate 120, corresponding to processing positions 312, along tracks 116, each of the tracks 116 to be scanned by one or more of the write beams 302. The movement of the substrate 120 is in an in-scan direction indicated by arrow 315, while the cross-scan direction is indicated by arrow 320. As the substrate 120 moves in the in-scan direction and cross-scan direction, an entirety of the surface 304 may be patterned by the write beams 302. The number of the IPS 301 may vary based on the size of the substrate 120 and/or the speed of stage 114. In one embodiment, there are 10 IPS 301 in the processing unit 104.

Each of the IPS 301 can include a light source 352, an aperture 354, a lens 356, a frustrated prism assembly 358, a spatial light modulator (SLM) 360 and a projection optical device 366. The components of each of the IPS 301 vary depending on the SLM 360 being used. Each SLM 360 includes, but is not limited to, an array of microLED's, VCSEL's, liquid crystal displays (LCDs), or any solid-state emitter of electromagnetic radiation, and a digital mirror device (DMD). Each SLM 360 can include SLM pixels. Each SLM pixel can be individually controllable to project a write beam. The compilation of SLM pixels forms the pattern written into the photoresist, referred to herein as the mask pattern. Each projection optical device 366 includes projection lenses, for example, 10× objective lenses, used to project light onto the substrate 120. In operation, based on the mask pattern data provided to the SLM 360 by the controller 110, each SLM pixel is at an “ON” position or “OFF” position. Each SLM pixel at an “ON” position forms a write beam that the corresponding projection optical device 366 then projects the write beam to the photoresist layer surface of the substrate 120 to form a pixel of the mask pattern. In some embodiments, each SLM 360 includes mirrors, e.g., the SLM pixels. Each of the mirrors corresponds to an SLM pixel that may correspond to a pixel of the mask pattern. In some embodiments, an SLM 360 is a DMD. In some embodiments, the DMD includes more than about 4,000,000 mirrors, while in other embodiments may include 1920×1080 mirrors, which represent the number of pixels of a high definition television.

The light source 352 is any suitable light source, such as a light emitting diode (LED) or a laser, capable of producing a light having a predetermined wavelength. In one embodiment, the predetermined wavelength is in the blue or near UV range, such as less than about 450 nm. The frustrated prism assembly 358 includes reflective surfaces. In operation, a light beam 453 having is produced by the light source 352. The light beam 353 is reflected SLM 360 by the frustrated prism assembly 358. When the light beam 353 reaches the mirrors of the SLM 360, each mirror at the “ON” position reflects the light beam 353 to the projection optical devices 366. The projection optical devices 366 then project write beams (e.g., “shots”) 302 onto the photoresist layer of the substrate 120. The write beams 302 form pixels of the mask pattern.

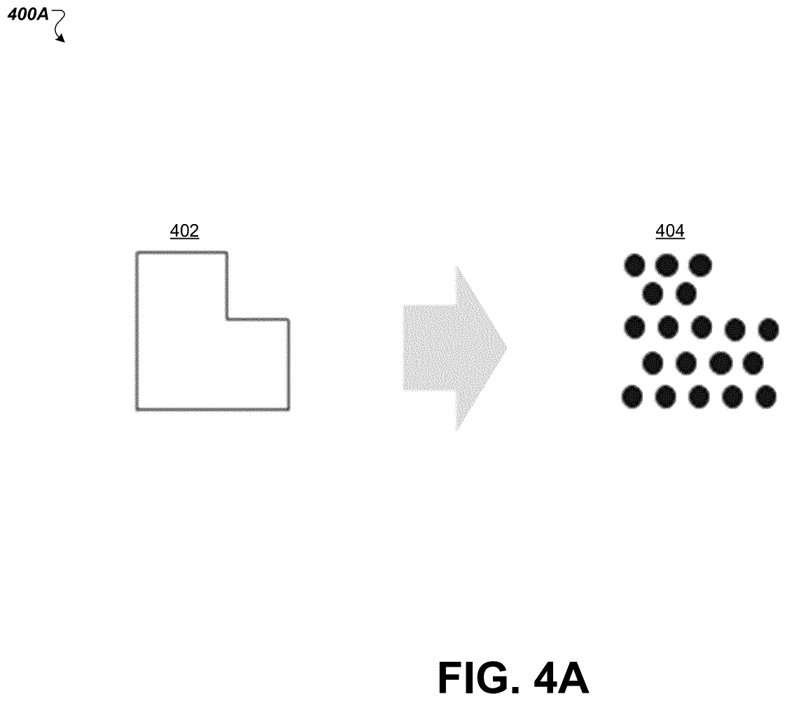

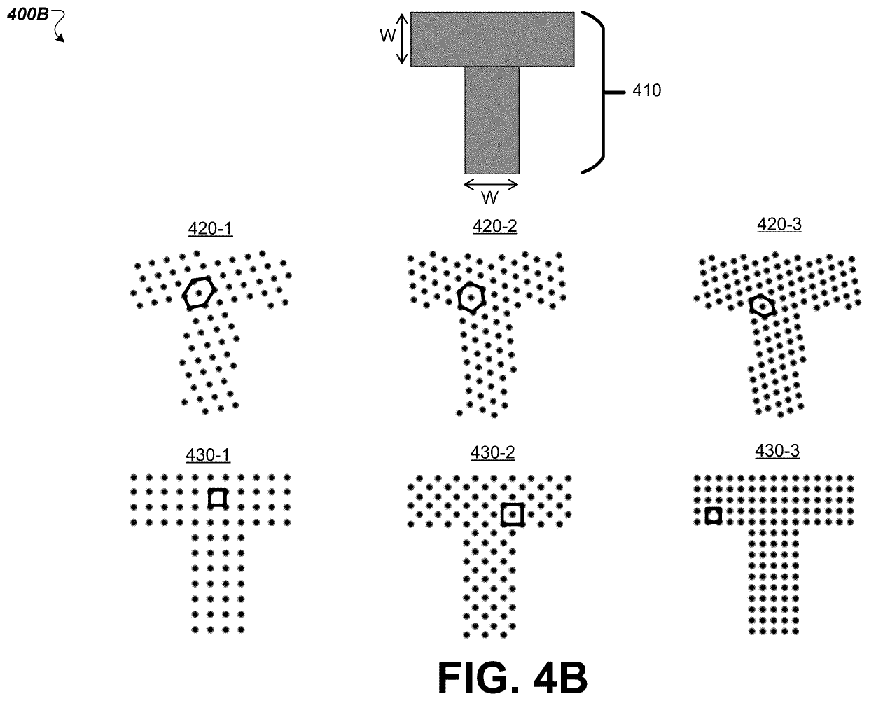

FIG. 4A includes diagrams 400A illustrating the transformation of a image 410 into a bitmap representation 420 of the image 410, in accordance with some embodiments. For example, the image 410 can be stored in a GDS file, and the bitmap representation 420 can be stored in a bitmap file. As will now be described below with reference to FIG. 4B, a pixel pattern can be used to transform the image 410 into the bitmap representation 420.

FIG. 4B includes diagrams 400B illustrating example rasterizations of an image 410 using pixel patterns, in accordance with some embodiments. For example, the image 410 can be a vector format image that is being rasterized into a raster image to be stored in a virtual mask file (e.g., GDS file). In this illustrative example, the image 410 is a T-shaped image defined by a pair of rectangles, which each rectangle has a width “W”. In some embodiments, W is less than or equal to 1 μm (e.g., sub-micron width).

For example, raster images 420-1 through 420-3 are each generated as a bitmap of pixels using a respective hexagon pixel pattern. The number of pixels for each of the raster images 420-1 through 420-3 can be chosen in accordance with a respective pixel density defined for the rasterization. In this example, the raster image 420-1 includes 74 pixels, the raster image 420-2 includes 92 pixels, and the raster image 420-3 includes 126 pixels. As can be seen in FIG. 4, the raster images 420-1 through 420-3 generated using respective hexagon pixel patterns exhibit LER and/or LWR.

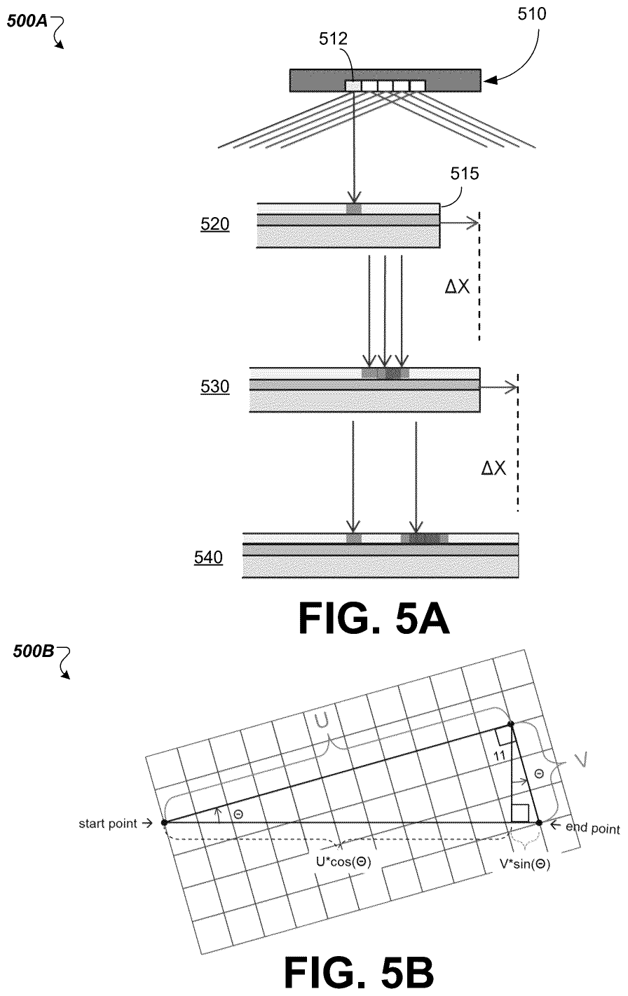

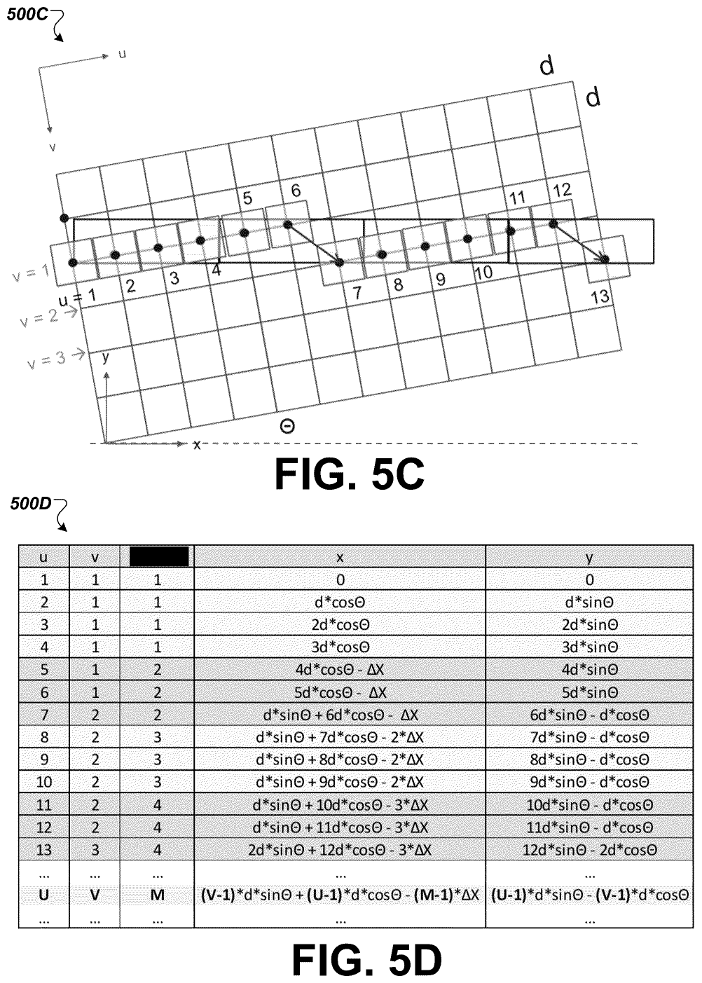

Raster images 430-1 and 430-3 are each generated using a respective square pixel pattern (e.g., non-rotated square pixel pattern), and raster image 430-2 is generated using a rotated square pixel pattern rotated relative to the non-rotated square pixel pattern (e.g., rotated about 45 degrees). The number of pixels for each of the raster images 430-1 through 430-3 can be chosen in accordance with a respective pixel density defined for the rasterization. In this example, the raster image 430-1 includes 72 pixels, the raster image 430-2 includes 90 pixels, and the raster image 430-3 includes 125 pixels. Accordingly, in addition to reducing or eliminating LER and/or LWF, the use of square pixel patterns that can be used to rasterize the image 410 can utilize fewer pixels as compared to the hexagon shaped patterns that can be used to rasterize the image 410. Further details regarding rasterizing shapes using square pixel patterns will now be described below with reference to FIGS. 5A-11.

FIG. 5A is a diagram 500A illustrating an example operation of a digital lithography system, in accordance with some embodiments. Diagram 500A shows a digital lithography system including a DMD 510 with DMD mirrors including mirror 512. During a first shot (e.g., exposure) 520, a region of a layer 515 is exposed. For example, the layer 515 can be a photoresist. After the first shot 520, the layer 515 can be moved by a distance ΔX with respect to the x-axis, and a second shot 530 is performed. The distance ΔX can be equal to the ratio of the scan speed v and the shot frequency f(ΔX=v/f). After the second shot 530 is performed, the layer 515 is moved by the distance ΔX and a third shot 540 is performed.

The exposed intensity of radiation (e.g., UV light) can have a Gaussian distribution, and some mirrors of the DMD may not operate correctly (e.g., defective pixels). To address this and improve resolution, a pixel blending technique can be used. For example, a pixel blending techniques can include exposing multiple shots within a unit pixel area on a substrate using pixel blending technology. The term “multiplicity” refers to the number of shots within a unit pixel area on the substrate. For example, assume that a mirror of a DMD has dimensions of 10 micrometers (μm)×10 μm. If a reduction lens reduces the dimensions by half, then the unit pixel area will be 5 μm×5 μm, and the multiplicity is the total number of shots contained within a 5 μm×5 μm unit pixel area. In the above illustrative example, if the DMD is not rotated, resolution may only be improved in the scan direction. To address this, and as will be described in further detail below with reference to FIG. 5B, the DMD can be rotated by an angle θ relative to the substrate or stage on which the substrate is placed. For example, assume that a shot from a laser is provided every T seconds(s), and the shot frequency f=1/T. Then, the substrate will be exposed every T s or every moving distance ΔX with respect to the x-axis, where ΔX is equal to the ratio of the scan speed v and the shot frequency f(ΔX=v/f). The exposure positions for each shot can be mathematically determined. The exposure positions can be accumulated to generate a pixel or dot pattern. Typically, the long-range distribution will not be uniform for arbitrary scan parameters (e.g., DMD rotation angle, scan speed, and shot frequency). Periodicity conditions can be used to obtain a uniform distribution pattern. However, the distribution may not be uniform in short-range point of view, so the proper multiplicity by changing it repeatedly. As the multiplicity increases, the exposure density will increase and resolution will be also improved, but will restrict the tool throughput. Further details regarding operation of the digital lithography system (e.g., to perform pixel blending) will now be described below with reference to FIGS. 5B-5C.

FIGS. 5B-5C are diagrams 500B-500C illustrating an example operation of a digital lithography system, in accordance with some embodiments. As shown in diagram 500B, a substrate can be divided into multiple cells corresponding to unit pixels having side lengths d. In the illustrative example described above with reference to FIG. 5A, d=5 μm. A first set of orthogonal axes (x, y) and a second set of orthogonal axes (u, v) are shown, where the second set of orthogonal axes correspond to the rotation of the DMD of the digital lithography system by an angle θ relative to the first set of orthogonal axes. In some embodiments, the first set of orthogonal axes (x, y) corresponds to axes of a substrate support or platform that holds a substrate during exposure. In embodiments, the second set of orthogonal axes (u, v) corresponds to axes of the DMD. The second set of axes may be rotated relative to the first set of axes in embodiments. The number of DMD mirrors along the scan direction can be equal to U.

Each pixel or dot generated by the digital lithography system can have a dot position represented by a respective (u, v) coordinate. The dot position can indicate the position of laser exposure with respect to the substrate. For example, in this illustrative example, a first dot has a dot position represented by the (u, v) coordinate of (1, 1), a second dot has a dot position represented by the (u, v) coordinate of (2, 1), a third dot has a dot position represented by the (u, v) coordinate of (3, 1), a fourth dot has a dot position represented by the (u, v) coordinate of (4, 1), a fifth dot has a dot position represented by the (u, v) coordinate of (5, 1), a sixth dot has a dot position represented by the (u, v) coordinate of (6, 1), a seventh dot has a dot position represented by the (u, v) coordinate of (7, 2), an eighth dot has a dot position represented by the (u, v) coordinate of (8, 2), a ninth dot has a dot position represented by the (u, v) coordinate of (9, 2), a tenth dot has a dot position represented by the (u, v) coordinate of (10, 2), an eleventh dot has a dot position represented by the (u, v) coordinate of (11, 2), a twelfth dot has a dot position represented by the (u, v) coordinate of (12, 2), and a thirteenth dot has a dot position represented by the (u, v) coordinate of (13, 3).

In this illustrative example, the first dot, the second dot, the third dot and the fourth dot define a first shot. The fifth dot, the sixth dot and the second dot define a second shot. The eighth dot, the ninth dot and the tenth dot define a third shot. The eleventh dot, the twelfth dot and the thirteenth dot define to a fourth shot. The total number of shots within a unit pixel area represents the multiplicity.

The (u, v) coordinate of a dot can be converted into a corresponding (x, y) coordinate based on the angle θ. For example, for the first shot, the first dot can have an x-coordinate of 0 and a y-coordinate of 0 by default (0, 0), the second dot can have an x-coordinate of dcos θ and a y-coordinate of dsin θ (dcos θ, dsin θ), the third dot can have an x-coordinate of 2 dcos θ and a y-coordinate of 2 dsin θ (2 dcos θ, 2 dsin θ), and the fourth dot can have an x-coordinate of 3 dcos θ and a y-coordinate of 3 dsin θ (3 dcos θ, 3 dsin θ).

As described above with reference to FIG. 5A, after each shot, the substrate can be moved by a distance ΔX with respect to the x-axis equal to the ratio of the scan speed v and the shot frequency f (ΔX=v/f). Therefore, for the second shot, the fifth dot can have an x-coordinate of 4 dcos θ−ΔX and a y-coordinate of 4 dsin θ (4 dcos θ−ΔX, 4 dsin θ), and the sixth dot can have an x-coordinate of 5 dcos θ−ΔX and a y-coordinate of 5 dsin θ (5 dcos θ−ΔX, 5 dsin θ). The seventh dot, which has a v-coordinate of 2 instead of 1, can have an x-coordinate of dsin θ+6 dcos θ−ΔX and a y-coordinate of 6 dsin θ-dcos θ (dsin θ+6 dcos θ−ΔX, 6 dsin θ−dcos θ).

For the third shot, the eighth dot can have an x-coordinate of dsin θ+7 dcos θ−2ΔX and a y-coordinate of 7 dsin θ−dcos θ (dsin θ+7 dcos θ−2ΔX, 7 dsin θ−dcos θ), the ninth dot can have an x-coordinate of dsin θ+8 dcos θ−2ΔX and a y-coordinate of 8 dsin θ−dcos θ (dsin θ+8 dcos θ−2ΔX, 8 dsin θ−dcos θ), and the tenth dot can have an x-coordinate of dsin θ+9 dcos θ−2ΔX and a y-coordinate of 9 dsin θ−dcos θ ((dsin θ+9 dcos θ−2ΔX, 9 dsin θ−dcos θ).

For the fourth shot, the eleventh dot can have an x-coordinate of dsin θ+10 dcos θ−3ΔX and a y-coordinate of 10 dsin θ−dcos θ (dsin θ+10 dcos θ−3ΔX, 10 dsin θ−dcos θ). The twelfth dot can have an x-coordinate of dsin θ+11 dcos θ−3ΔX and a y-coordinate of 11 dsin θ−dcos θ (dsin θ+11 dcos θ−3ΔX, 11 dsin θ−dcos θ). The thirteenth dot, which has a v-coordinate of 3 instead of 2, can have x-coordinate of 2 dsin θ+12 dcos θ−3ΔX and a y-coordinate of 12 dsin θ−2 dcos θ (2 dsin θ+12 dcos θ−3ΔX, 12 dsin θ−2 dcos θ).

In view of the above, for a general dot position of a dot represented by the coordinate (U, V) corresponding to shot M, the x-coordinate for the dot can be defined by (V−1)dsin θ+(U−1)dcos θ−(M−1)ΔX and the y-coordinate for the dot can be defined by (U−1)dsin θ−(V−1) dcos θ.

As shown in FIG. 5B, the DMD rotation angle θ can satisfy the equation tan θ=V/U. In other words, θ=arctan(V/U). As further shown in FIG. 5B, the total moving distance from the start point to the end point is equal to Vdsin θ+Udcos θ. The total moving distance should be equal to MAX, where M is the multiplicity. That is Vdsin θ+Udcos θ=MAX.

FIG. 5C shows two types of unit pixels. A first type of unit pixel is a square unit pixel having dimensions d×d, and a second type of unit pixel is a rectangular unit pixel having dimensions d ΔXcos θ. The total number of dots within the first type of unit pixel can be equal to the multiplicity. The total number of dots within the second type of unit pixel can be equal to U.

FIG. 5D is a table 500D showing for each dot, the (u, v) coordinate, the corresponding shot or multiplicity for the dot, the conversion of the u-coordinate into a respective x-coordinate, and the conversion of the v-coordinate into a respective y-coordinate.

Since each of the exposure positions on the substrate can be determined by the information shown in the table 500D, a dot or pixel distribution can be generated by selecting proper parameters, such as (1) the projected mirror length d (2) the DMD rotation angle θ, *3) the number of mirrors in the scan direction U, 4) V (depends on rotation angle), (5) the multiplicity M, (6) the scan speed v, and (7) the laser pulse frequency f. For example, the dot or pixel distribution pattern for the pattern shown in FIG. 4B can be generated with the parameters of d=2.749 μm, U=1,499, V=51, 0=34.01 milliradians (mrad), M=147, v=200 mm/see, and f=14,989 Hz.

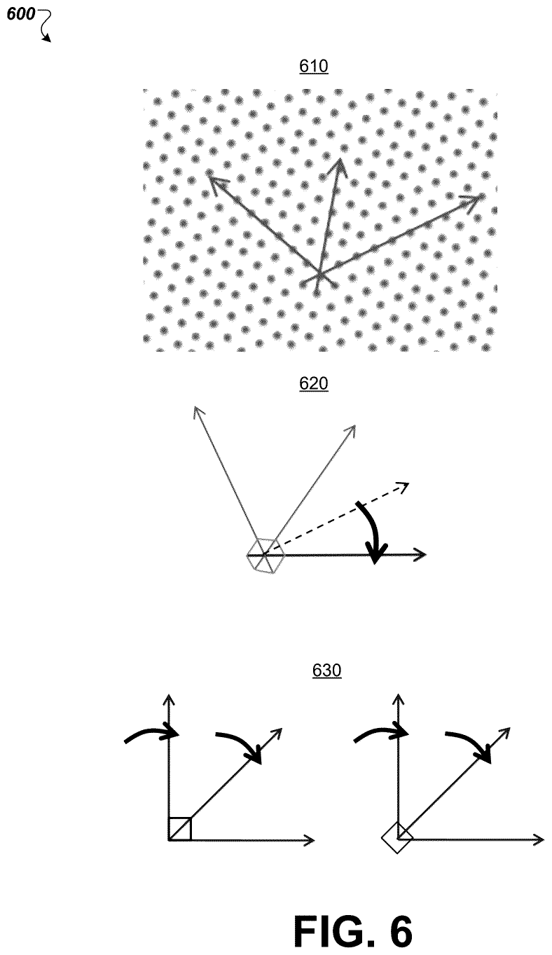

In the example shown in FIG. 5C, a periodicity condition is not applied, and the long-range pixel distribution may not be uniform. A periodicity condition can be applied to achieve a long-range uniform pixel distribution. Even if the periodicity condition is applied, the short-range pixel distribution may still not uniform. To address this, an appropriate multiplicity can be determined. By using the formula shown in the table 500D, different pixel distribution patterns can be obtained by changing the multiplicity and/or scan speed. Further details regarding the periodicity condition and determining the appropriate multiplicity will now be described below with reference to FIGS. 6-11,

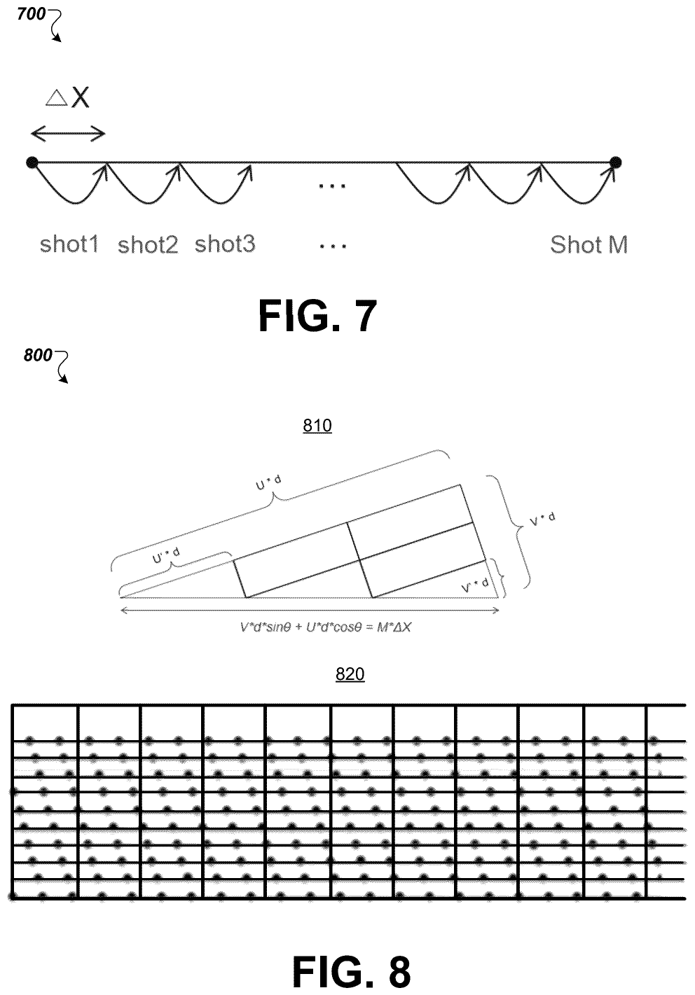

FIG. 6 are diagrams 600 illustrating example steps of forming square pixel patterns for high resolution digital lithography using a DMD that is rotated relative to a substrate being exposed by the DMD, in accordance with some embodiments. For example, diagram 600 shows a uniform pattern distribution 610 obtained after applying periodicity conditions during a first step of a method of square pixel pattern formation. The uniform pattern distribution 610 is shown with a pair of non-orthogonal axes. Generally, a periodicity condition defines a periodic cycle of shots performed by a digital lithography system (e.g., DMD). Further details regarding applying periodicity conditions will be described in further detail below with reference to FIG. 7.

Diagram 620 shows that during a second step of the method of square pixel pattern formation, one axis of the pair of non-orthogonal axes is rotated to become parallel to a first orthogonal axis (e.g., the x-axis) by confining values of a second orthogonal axis, perpendicular to the first orthogonal axis (e.g., y-axis values), to a number of lines perpendicular to the second orthogonal axis (e.g., parallel to the first orthogonal axis). That is, the first orthogonal axis can be a horizontal axis and the second orthogonal axis can be a vertical axis. Further details regarding the second step will be described below with reference to FIG. 8.

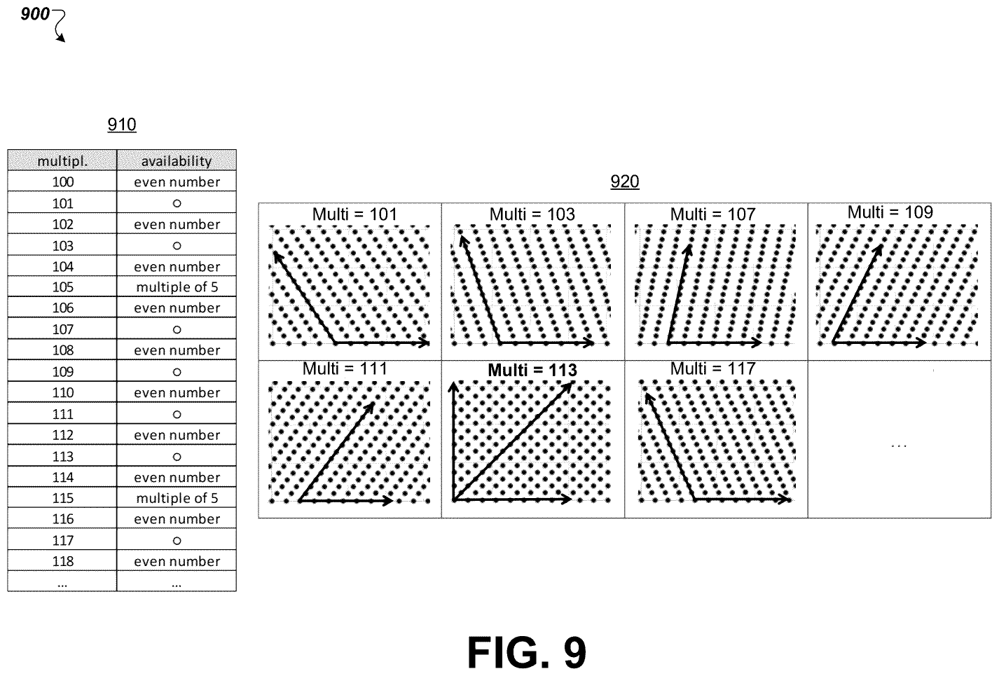

Diagram 630 shows that during a third step of the method of square pixel pattern formation, the other axis of the pair of non-orthogonal axes is rotated to become parallel to the second orthogonal axis (e.g., the y-axis) by confining values of the first orthogonal axis (e.g., x-axis values) to a number of lines perpendicular to the second orthogonal axis (e.g., parallel to the first orthogonal axis). Further details regarding the third step will be described below with reference to FIG. 9.

FIG. 7 is a diagram 700 illustrating an example of applying periodicity conditions used to implement square pixel patterns for high resolution digital lithography, in accordance with some embodiments. As shown in FIG. 7, the number of shots performed by a digital lithography system (e.g., DMD) within a periodic cycle of shots can be defined by a multiplicity M (e.g., shot 1, shot 2, shot 3, . . . , shot M). As described above with reference to FIGS. 5A-5B, after each shot, the substrate can be moved by a distance ΔX with respect to the x-axis equal to the ratio of the scan speed v and the shot frequency f (ΔX=v/f).

One periodicity condition is that a position of the initial dot of the next shot M+1, which is the first shot of the next periodic cycle of shots (not shown in FIG. 7), should be the same as the position of the initial dot of shot 1. Mathematically, with reference to FIGS. 5A-5D, this periodicity condition can be captured by the general relation f(U+1, V+1, M+1)=f (1, 1, 1)={0, 0}. As described above with reference to FIGS. 5A-5D, for a dot represented corresponding to a shot M, the x-coordinate for the dot can be defined by (V−1)dsin θ+(U−1)dcos θ(M−1)ΔX and the y-coordinate for the dot can be defined by (U−1)dsin θ−(V−1) dcos θ. Plugging this into the periodicity condition, f(U+1, V+1, M+1)={Vdsin θ+Udcos θ−MΔX, Udsin θ−Vdcos θ}={0, 0}. Accordingly, the periodicity condition can be satisfied if the initial dot of shot M+1 satisfies both Vdsin θ+Udcos θ=0 and Vdsin θ+Udcos θ=0.

FIG. 8 is a diagram illustrating an example of confining values of a first axis to number of lines perpendicular to the first axis used to implement square pixel patterns for high resolution digital lithography, in accordance with some embodiments. For example, the value of the first axis can be y-coordinate values, and the lines perpendicular to the first axis can be horizontal lines.

As shown, diagram 810 shows a base triangle having a first side along the u-axis with a length equal to U*d (where d is the length of a cell), a second side along the v-axis with a length equal to V*d, and a third side having a length equal to V*d*sin θ+(*d*cos θ=M*ΔX (which is the total moving distance as described above with reference to FIGS. 5A-5B). Diagram 810 further shows a first inscribed triangle having a side along the u-axis having a length U′*d, and a second inscribed triangle having a side along the y-axis having a length V′*d. The following relationship can be satisfied: U/V=NU′/NV′=U′/V′.

If U and V do not have any common divisor (e.g., U and V do not share any prime factors), then, for each dot in a cell, the y-coordinate of the (x, y) coordinate for the dot is different. More specifically, the y-coordinate for a dot having a coordinate (u, v) can be defined by udsin θ-vdcos θ, and the number of y-coordinates is equal to U. The value U can correspond to the number of mirrors along a scan direction to complete one cycle.

If U and V have at least one common divisor (e.g., U and V share at least one prime factor), then the number of y-coordinates can be reduced to U/N, where N is the greatest common divisor of U and V. All dots within a cell can be confined onto a limited number of horizontal lines. More specifically, the y-coordinate for a dot can be defined by N(U′dsin θ−V′dcos θ).

As an illustrative example, assume that U=1500 which has a prime factorization of 2×3×5×5×5×2, and V=150 which has a prime factorization of 2×3×5×5. The DMD rotation angle θ is equal to arctan(150/1500) which is approximately equal to 0.1 radians or 5.71 degrees. The common divisors are 2, 3, 5 and 5, meaning that the greatest common divisor is 150. Thus, the number of y-coordinates are confined onto 10 horizontal lines the shots are exposed along the 10 horizontal lines. Diagram 820 shows an example of dots having y-coordinates confined to 10 horizontal lines.

FIG. 9 includes diagrams illustrating an example of confining values of a second axis to a number of lines perpendicular to the second axis used to implement square pixel patterns for high resolution digital lithography, in accordance with some embodiments. For example, the value of the second axis can be x-coordinate values, and the lines perpendicular to the second axis can be vertical lines.

Confining the values of the second axis to the number of lines perpendicular to the second axis can be done by identifying the proper multiplicity (i.e., number of shots) that makes the other axis vertical or 45 degrees. The multiplicity can be selected from a predefined multiplicity range that can be specified based on factors such as pattern resolution and stage scan speed. Illustratively, the multiplicity range can range from 100 to 200. Multiplicities that are multiples of common divisors of U and V can be skipped to avoid duplicated pixel blending.

To illustrate the concept, diagram 910 is a table identifying available candidate multiplicities greater than or equal to 100 if U=1500=2×2×5×5×5×3 and V=100=2×2×5×5. Candidate multiplicities are indicated by a circle, while the other multiplicities are excluded as being multiples of common divisors, and in particular multiples of 2 (even numbers), and multiples of 5. Diagram 920 illustrate the resulting axes for some of the candidate multiplicities (e.g., 101, 103, 107, 109, 11, 113, 117). Multiplicity 113 is selected as the proper multiplicity among the candidate multiplicities as it results in a perpendicular y-axis (as opposed to the other multiplicities that result in non-perpendicular axes relative to the x-axis). Points along the diagonal axis having a 45 degree angle relative to the x-axis have x-coordinate values equal to y-coordinate values.

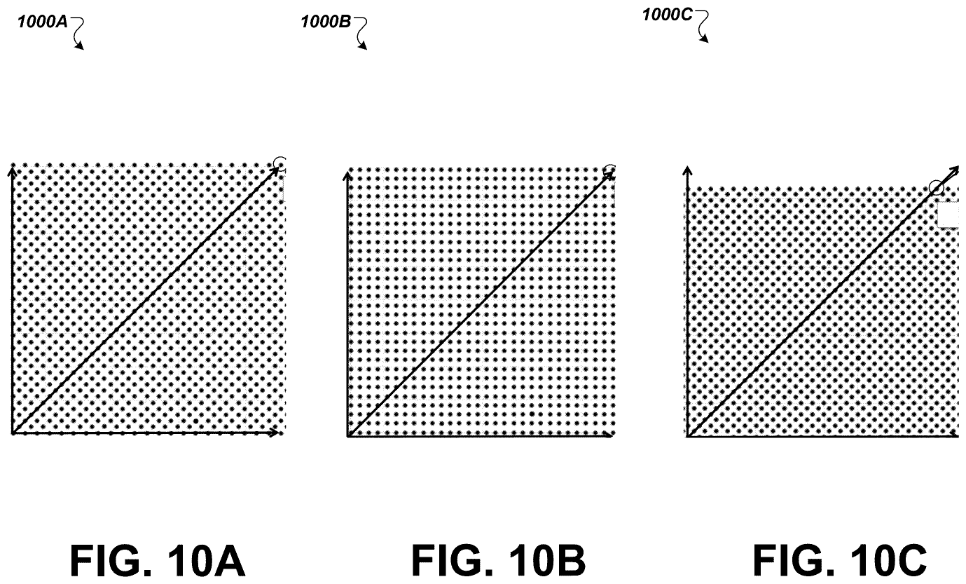

FIGS. 10A-10C are diagrams illustrating example implementations of square pixel patterns for high resolution digital lithography, in accordance with some embodiments. For example, FIG. 10A is a diagram showing an example of a stack of three unit pixel areas generated using a rotated square pixel pattern. In this example it is assumed that U=1500=2×2×3×5×5×5 and that V=100=2×2×5×5. The DMD rotation angle θ is equal to arctan(100/1500) which is approximately equal to 0.067 radians or 3.81 degrees. The common divisors are 2, 2, 5 and 5, meaning that the greatest common divisor is 100. Thus, the number of y-coordinates within each unit pixel area are confined onto 15 horizontal lines. That is, all of the shots within each unit pixel area are exposed along the 15 horizontal lines (5×3, which are the remaining factors of U after dividing by V). As described above with reference to FIG. 9, the proper multiplicity is 113.

FIG. 10B is a diagram showing an example of a stack of three unit pixel areas generated using a non-rotated square pixel pattern. In this example it is assumed that U=1500=2×2×3×5×5×5 and that V=150=2×3×5×5. As described above with reference to FIG. 8, the DMD rotation angle θ is equal to arctan(150/1500) which is approximately equal to 0.1 radians or 5.71 degrees and the number of y-coordinates within each unit pixel area are confined onto 10 horizontal lines (2×5, which are the remaining factors of U after dividing by V). That is, all of the shots within each unit pixel area are exposed along the 10 horizontal lines. It can be shown that the proper multiplicity is 101.

FIG. 10C is a diagram showing an example of a three unit pixel areas generated using a rotated square pixel pattern. In this example it is assumed that U=1500 and that V=700. The DMD rotation angle θ is equal to arctan(700/1500) which is approximately equal to 0.44 radians or 25 degrees. The common divisors are 2, 2, 5 and 5, meaning that the greatest common divisor is 100. Thus, the number of y-coordinates within each unit pixel area are confined onto 15 horizontal lines (5×3, which are the remaining factors of U after dividing by V). That is, all of the shots within each unit pixel area are exposed along the 15 horizontal lines. It can be shown that the proper multiplicity is 137.

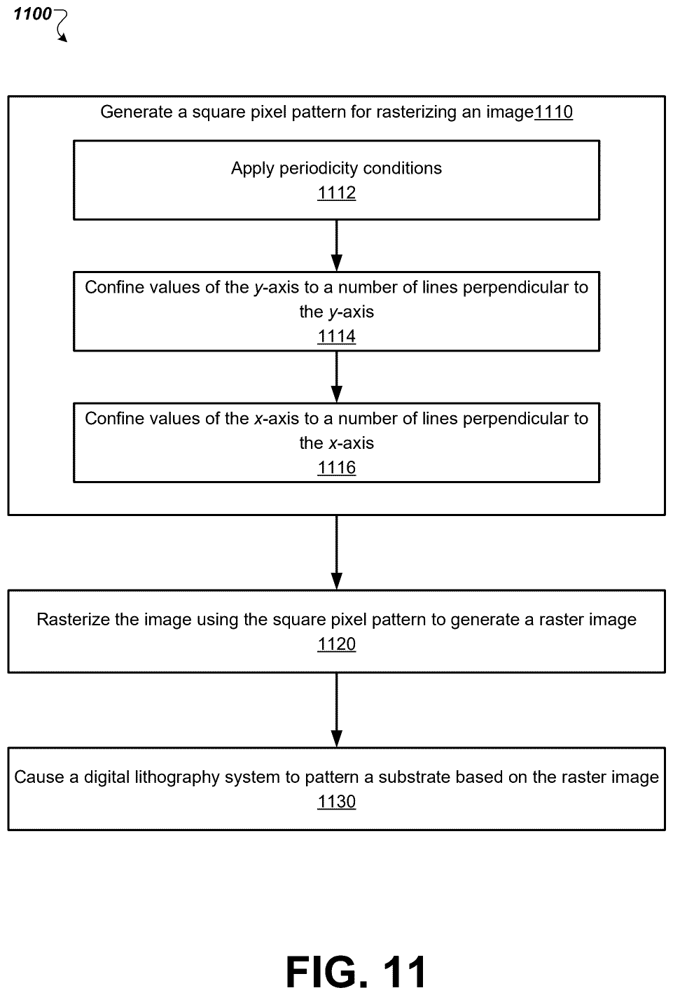

FIG. 11 depicts a flow diagram of a method 1100 for implementing square pixel patterns for high resolution digital lithography g, in accordance with some embodiments. The method 1100 may be performed by processing logic that may comprise hardware (circuitry, dedicated logic, etc.), computer readable instructions (run on a general purpose computer system or a dedicated machine), or a combination of both. In an illustrative example, method 1100 may be performed by a processing device of a digital lithography system. It should be noted that blocks depicted in FIG. 11 could be performed simultaneously or in a different order than that depicted.

At block 1110, processing logic generates a square pixel pattern for rasterizing an image. In some embodiments, the square pixel pattern is a non-rotated square pixel pattern. In some embodiments, the square pixel pattern is a rotated square pixel pattern.

For example, generating the square pixel pattern can include applying periodicity conditions at block 1112. The periodicity conditions can include a condition that for periodic cycles defined by a shot multiplicity (e.g., M), a position of an initial dot of an initial shot of a first periodic cycle (e.g., the initial dot of shot 1) is equal to the position of an initial dot of an initial shot of a second periodic cycle following the first periodic cycle (e.g., the initial dot of shot M+1). From this periodicity condition, other conditions follow. For example, the total moving distance along the x-axis from the start point to the end point (MAX) is equal to the sum of a first projection of the total moving distance along a first axis rotated relative to the x-axis (e.g., u-axis) and a second projection of the total moving distance along a second axis perpendicular to the first axis (e.g., v-axis). More specifically, the first axis can be rotated by the DMD rotation angle θ relative to the x-axis and the second axis can be rotated by the DMD rotation angle θ relative to the y-axis. For example, as described above with reference to FIGS. 5A-7, the periodicity condition can impose the following relationships: Vdsin θ+Udcos θ−MAX=θ and Udsin θ−Vdcos θ=0. U is equal to the number of cells traversed along the u-axis from the start point to the end point, Vis equal to the number of cells traversed along the v-axis from the start point to the end, θ=arctan (VIU), d is the length of a cell of a grid rotated by the DMD rotation angle θ relative to the x-axis, Ud is the total moving distance along the u-axis, Vd is the total moving distance along the v-axis, Udcos θ is the first projection, Vdsin θ is the second projection, Udsin θ is a third projection of the total moving distance along the v-axis, and Vdcos θ is a fourth projection of the total moving distance along the v-axis.

As another example, generating the square pixel pattern can include confining values of the y-axis (i.e., y-coordinates) to a number of lines perpendicular to the y-axis at block 1114. More specifically, the lines perpendicular to the y-axis can be horizontal lines (e.g., parallel to the x-axis). Confining the values to the y-axis can include determining whether the number of cells traversed along the first axis (e.g., the u-axis) is coprime with respect to the number of cells traversed along the second axis (e.g., the v-axis). That is, confining the values to the y-axis can include determining whether U and V are coprime.

If U and V are coprime, then each dot in a cell of the grid can have a different y-coordinate, the y-coordinate of a dot having position (u, v) can be equal to udsin θ-vdcos θ, and the number of available y-coordinates is equal to U. Accordingly, all dots within a cell are confined to a number of horizontal lines equal to U.

If U and V are not coprime (i.e., they have at least one common divisor), then the number of available y-coordinates is equal to U/N, where N is the greatest common divisor of U and V. The y-coordinate of a dot having position (u, v) can be equal to N (u′dsin θ-v′dcos θ), as described above with reference to FIG. 8. Accordingly, all dots within a cell are confined to a reduced number of horizontal lines equal to U/N.

As yet another example, generating the square pixel pattern can include confining values of the x-axis (i.e., y-coordinates) to a number of lines perpendicular to the x-axis at block 1116. More specifically, the lines perpendicular to the x-axis can be verticals lines (e.g., parallel to the y-axis). Confining the values to the x-axis can include identifying a multiplicity of shots that results in an arrangement of dots that defines a y-axis perpendicular to the x-axis. The multiplicity of shots can be selected from a set of candidate multiplicities. The set of candidate multiplicities can be included within a predefined range of multiplicities specified based on factors such as pattern resolution, stage scan speed, etc. To avoid pixel blending, only candidate multiplicities that are not common divisors of U may be considered. Further details regarding block 1116 are described above with reference to FIG. 9.

At block 1120, processing logic rasterizes the image using the square pixel pattern to generate a raster image. The raster image can be stored in a file that is usable by a digital lithography system to pattern a substrate (e.g., a GDS file).

At block 1130, processing logic causes a digital lithography system to pattern a substrate based on the raster image. A photoresist can be formed on the substrate. For example, causing the digital lithography system to pattern the substrate can include causing a light source (e.g., laser or LED) to generate light. In some embodiments, the digital lithography system includes a DMD including a plurality of mirrors, and causing the digital lithography system to pattern the substrate can include controlling a state of each mirror of the plurality of mirrors based on the raster image. The substrate can be placed on a movable stage, and causing the digital lithography system to pattern the substrate can include controlling a position of the substrate by moving the movable stage. Further details regarding blocks 1110-1130 are described above with reference to FIGS. 1-10C.

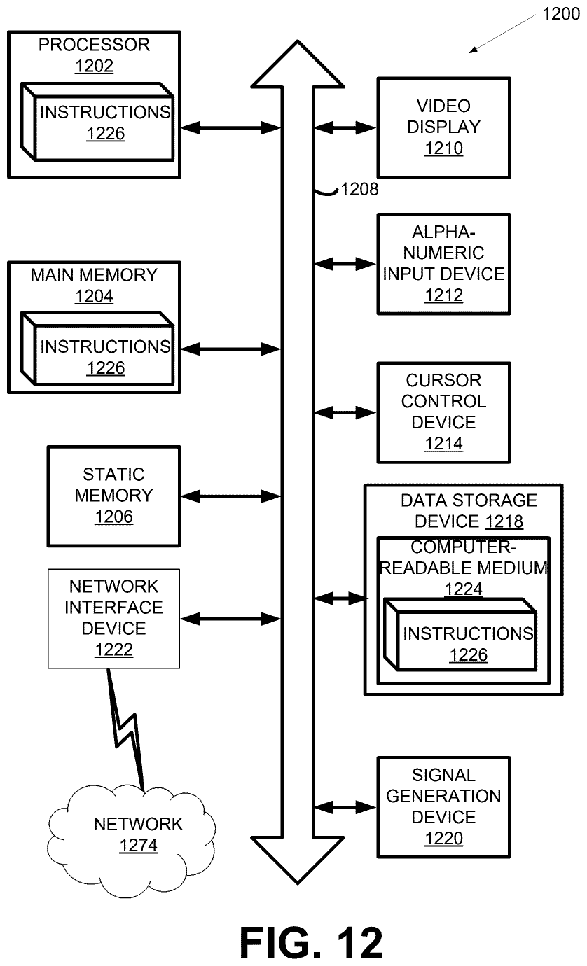

FIG. 12 is a block diagram illustrating a computer system 1200, according to certain embodiments. In some embodiments, computer system 1200 is connected (e.g., via a network 1274, such as a Local Area Network (LAN), an intranet, an extranet, or the Internet) to other computer systems. In some embodiments, computer system 1200 operates in the capacity of a server or a client computer in a client-server environment, or as a peer computer in a peer-to-peer or distributed network environment. In some embodiments, computer system 1200 is provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein.

In a further aspect, the computer system 1200 includes a processing device 1202, a volatile memory 1204 (e.g., Random Access Memory (RAM)), a non-volatile memory 1206 (e.g., Read-Only Memory (ROM) or Electrically-Erasable Programmable ROM (EEPROM)), and a data storage device 1216, which communicate with each other via a bus 1208.

In some embodiments, processing device 1202 is provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

In some embodiments, computer system 1200 further includes a network interface device 1222 (e.g., coupled to network 1274). In some embodiments, computer system 1200 also includes a video display unit 1210 (e.g., an LCD), an alphanumeric input device 1212 (e.g., a keyboard), a cursor control device 1214 (e.g., a mouse), and a signal generation device 1220.

In some implementations, data storage device 1216 includes a non-transitory computer-readable storage medium 1224 to store instructions 1226 encoding any one or more of the methods or functions described herein. For example, the instructions 1226 can include instructions for controlling the movement of the stage and/or exposure units of a digital lithography system, which, when executed, can implement the methods for performing exposure unit boundary smoothing described herein.

In some embodiments, instructions 1226 also reside, completely or partially, within volatile memory 1204 and/or within processing device 1202 during execution thereof by computer system 1200, hence, in some embodiments, volatile memory 1204 and processing device 1202 also constitute machine-readable storage media.

While the non-transitory computer-readable storage medium 1224 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

In some embodiments, the methods, components, and features described herein are implemented by discrete hardware components or are integrated in the functionality of other hardware components such as ASICS, FPGAs, DSPs or similar devices. In some embodiments, the methods, components, and features are implemented by firmware modules or functional circuitry within hardware devices. In some embodiments, the methods, components, and features are implemented in any combination of hardware devices and computer program components, or in computer programs.

Unless specifically stated otherwise, terms such as “receiving,” “initiating,” “performing,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. In some embodiments, the terms “first,” “second,” “third,” “fourth,” etc. as used herein are meant as labels to distinguish among different elements and do not have an ordinal meaning according to their numerical designation.

Examples described herein also relate to an apparatus for performing the methods described herein. In some embodiments, this apparatus is specially constructed for performing the methods described herein, or includes a general purpose computer system selectively programmed by a computer program stored in the computer system. Such a computer program is stored in a computer-readable tangible storage medium.

The methods and illustrative examples described herein are not inherently related to any particular computer or other apparatus. In some embodiments, various general purpose systems are used in accordance with the teachings described herein. In some embodiments, a more specialized apparatus is constructed to perform methods described herein and/or each of their individual functions, routines, subroutines, or operations. Examples of the structure for a variety of these systems are set forth in the description above.

The preceding description sets forth numerous specific details such as examples of specific systems, components, methods, and so forth, in order to provide a good understanding of several embodiments of the present invention. It will be apparent to one skilled in the art, however, that at least some embodiments of the present invention may be practiced without these specific details. In other instances, well-known components or methods are not described in detail or are presented in simple block diagram format in order to avoid unnecessarily obscuring the present invention. Thus, the specific details set forth are merely exemplary. Particular implementations may vary from these exemplary details and still be contemplated to be within the scope of the present invention.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within +10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other implementation examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

What is claimed is:

1. A system comprising:
a memory; and
at least one processing device, operatively coupled to the memory, to:
generate a square pixel pattern for rasterizing an image;
rasterize the image using the square pixel pattern to generate a raster image,
wherein the raster image is stored in a file usable by a digital lithography system; and
cause the digital lithography system to pattern a substrate based on the raster image having the square pixel pattern.

2. The system of claim 1, wherein, to generate the square pixel pattern, the at least one processing device is to apply a set of periodicity conditions.

3. The system of claim 2, wherein the set of periodicity conditions comprises a condition that a position of an initial dot of an initial shot of a first periodic cycle is equal to the position of an initial dot of an initial shot of a second periodic cycle following the first periodic cycle.

4. The system of claim 1, wherein, to generate the square pixel pattern, the at least one processing device is to confine values of a y-axis, defined relative to the substrate, to a number of lines perpendicular to the y-axis.

5. The system of claim 4, wherein, to confine the values of the y-axis, the at least one processing device is to determine whether a first number of cells traversed along a first axis is coprime with respect to a second number of cells traversed along a second axis perpendicular to the first axis, and wherein the first axis is rotated relative to an x-axis, defined relative to the substrate, by a rotation angle of a digital micromirror device (DMD) of the digital lithography system.

6. The system of claim 5, wherein, to confine the values of the y-axis, the at least one processing device is further to, in response to determining that the first number of cells is coprime with respect to the second number of cells, confine each dot within a cell to a number of lines equal to the first number of cells.

7. The system of claim 5, wherein, to confine the values of the y-axis, the at least one processing device is further to, in response to determining that the first number of cells is not coprime with respect to the second number of cells, confine each dot within a cell to a number of lines equal to the first number of cells divided by a greatest common divisor of the first number of cells and the second number of cells.

8. The system of claim 1, wherein, to generate the square pixel pattern, the at least one processing device is to confine values of an x-axis, defined relative to the substrate, to a number of lines perpendicular to the x-axis.

9. The system of claim 8, wherein, to confine the values of the x-axis, the at least one processing device is to identify a multiplicity of shots that results in an arrangement of dots that defines a y-axis perpendicular to the x-axis.

10. A method comprising:
generating, by at least one processing device, a square pixel pattern for rasterizing an image;
rasterizing, by the at least one processing device, the image using the square pixel pattern to generate a raster image, wherein the raster image is stored in a file usable by a digital lithography system; and
causing, by the at least one processing device, the digital lithography system to pattern a substrate based on the raster image having the square pixel pattern.

11. The method of claim 10, wherein generating the square pixel pattern comprises applying a set of periodicity conditions.

12. The method of claim 11, wherein the set of periodicity conditions comprises a condition that a position of an initial dot of an initial shot of a first periodic cycle is equal to the position of an initial dot of an initial shot of a second periodic cycle following the first periodic cycle.

13. The method of claim 10, wherein generating the square pixel pattern comprising confining values of a y-axis, defined relative to the substrate, to a number of lines perpendicular to the y-axis.

14. The method of claim 13, wherein confining the values of the y-axis comprises determining whether a first number of cells traversed along a first axis is coprime with respect to a second number of cells traversed along a second axis perpendicular to the first axis, and wherein the first axis is rotated relative to an x-axis, defined relative to the substrate, by a rotation angle of a digital micromirror device (DMD) of the digital lithography system.

15. The method of claim 14, wherein confining the values of the y-axis further comprises, in response to determining that the first number of cells is coprime with respect to the second number of cells, confining each dot within a cell to a number of lines equal to the first number of cells.

16. The method of claim 14, wherein confining the values of the y-axis further comprises, in response to determining that the first number of cells is not coprime with respect to the second number of cells, confining each dot within a cell to a number of lines equal to the first number of cells divided by a greatest common divisor of the first number of cells and the second number of cells.

17. The method of claim 10, wherein generating the square pixel pattern comprises confining values of an x-axis, defined relative to the substrate, to a number of lines perpendicular to the x-axis.

18. The method of claim 17, wherein confining the values of the x-axis comprises identifying a multiplicity of shots that results in an arrangement of dots that defines a y-axis perpendicular to the x-axis.

19. A non-transitory computer-readable storage medium comprising instructions that, when executed by at least one processing device, cause the processing device to perform operations comprising:
generating a square pixel pattern for rasterizing an image;
rasterizing the image using the square pixel pattern to generate a raster image, wherein the raster image is stored in a file usable by a digital lithography system; and
causing the digital lithography system to pattern a substrate based on the raster image having the square pixel pattern.

20. The non-transitory computer-readable storage medium of claim 19, wherein generating the square pixel pattern comprises:
applying a set of periodicity conditions, wherein the set of periodicity conditions comprises a condition that a position of an initial dot of an initial shot of a first periodic cycle is equal to the position of an initial dot of an initial shot of a second periodic cycle following the first periodic cycle;
confining values of a y-axis, defined relative to the substrate, to a number of lines perpendicular to the y-axis; and
confining values of an x-axis, defined relative to the substrate, to a number of lines perpendicular to the x-axis.
